(19) United States
(12) Patent Application Publication
(10) Pub. No.: US 2023/0420354 A1
(43) Pub. Date: Dec. 28, 2023

(54) ELECTRICAL CONDUCTOR EXTENDING FROM A SURFACE OF A SUBSTRATE

(71) Applicant: Intel Corporation, Santa Clara, CA (US)

(72) Inventors: Telesphor KAMGAING, Chandler, AZ (US); Chee Kheong YOON, Bayan Lepas (MY); Chu Aun LIM, Hillsboro, OR (US); Eng Huat GOH, Ayer Itam (MY); Min Suet LIM, Gelugor (MY); Kavitha NAGARAJAN, Bangalore (IN); Jooi Wah WONG, Bukit Mertajam (MY)

(21) Appl. No.: 17/848,643

(22) Filed: Jun. 24, 2022

(51) Int. Cl. H01L 23/498; H01L 21/48; H05K 1/18

(52) U.S. Cl. CPC H01L 23/49838; H01L 23/49816; H01L 23/49827; H01L 21/4853; H05K 1/181; H01L 23/49822; H05K 2201/10378; H05K 2201/10734

(57) ABSTRACT

Embodiments herein relate to systems, apparatuses, techniques, or processes directed to an electrical conductor, or power corridor, on the outside of a package substrate, wherein the electrical conductor is raised, or extends from a surface of the package substrate. In embodiments, this electrical conductor may be used to reduce the number of layers required within the package substrate by removing power planes within the substrate to the electrical conductors on the surface of the package. Other embodiments may be described and/or claimed.

### FIELD

Embodiments of the present disclosure generally relate to the field of package assemblies, and in particular package assemblies that include power domains.

### BACKGROUND

Continued reduction in end product size of mobile electronic devices such as smart phones and ultrabooks is a driving force for the development of reduced size system in package components. In particular, reducing the Z-height of semiconductor packages.

### BRIEF DESCRIPTION OF THE DRAWINGS

FIG. 1 illustrates a cross section side view and a top-down view of a legacy package coupled with a printed circuit board (PCB), where a package substrate includes multiple power planes.

FIGS. 2A-2B illustrate cross section side views of a package that includes electrical conductors on a side of a package substrate that extend from a surface of the package substrate, in accordance with various embodiments.

FIG. 3 shows a comparison between the number of layers of a legacy package substrate and the number of layers of a package that includes electrical conductors on a surface of the package substrate, in accordance with various embodiments.

FIGS. 4A-4D illustrate layouts of one or more electrical conductors on a surface of a package substrate, in accordance with various embodiments.

FIG. 5A-5C illustrate a cross section side view and top down views of a package that includes electrical conductor on a die side surface of a package substrate, in accordance with various embodiments.

FIG. 6 illustrates an example of a process for creating a package that includes a substrate with an electrical conductor on a surface of the package substrate, in accordance with various embodiments.

FIG. 7 schematically illustrates a computing device, in accordance with various embodiments.

### DETAILED DESCRIPTION

Embodiments of the present disclosure may generally relate to systems, apparatus, and/or processes directed to creating an electrical conductor, or power corridor, on the outside of a package substrate, wherein the electrical conductor is raised, or extends from a surface of the package substrate. In embodiments, this electrical conductor may be used to reduce the number of layers required within the package substrate by removing power planes within the substrate to the electrical conductors on the surface of the package. In embodiments, there may be more than one electrical conductor on a surface of a package substrate, for example to route different power domains.

In embodiments, the electrical conductor, which may also be referred to as a power corridor, a power rail, a power plane, an external power plane, or an electrical bus, a power net, may be formed on a surface of a substrate using, for example metal deposition techniques. In embodiments, the electrical conductor may be pre-formed, and applied to a surface of the substrate. These embodiments may be used to provide extra stiffening for the package substrate, particular for thin substrates, or substrates that have no core or a very thin core. In embodiments, the core may include glass, ceramic, photo definable glass, or copper clad laminate (CCL). In nonlimiting embodiments, the glass core may have a thickness ranging from 40 μm 250 μm.

In embodiments, the electrical conductor may be formed or placed by a surface of a substrate that includes one or more electrical connections. In particular, the electrical conductor may be placed on the bottom surface of the substrate that couples with a PCB using a ball grid array (BGA). In embodiments, the electrical conductor may have a thickness above the surface of the substrate that allows portions of the electrical conductor to fit between individual balls of the BGA, and does not interfere with the coupling of the substrate with the BGA. In particular, the thickness of the electrical conductor may be the same or less than a distance between the surface of the substrate and the surface of the PCB. In embodiments, this thickness may be substantially thicker than the thickness of legacy traces or routings at the surface of the substrate.

In embodiments, using the electrical conductor as described herein may be used to reduce package layer counts, which may decrease costs and also address anticipated supply-chain constraints in the near and long-term. Reducing package layer counts also reduces the overall Z-height of the package. In embodiments, reducing the number of layers in the package involves removing layers that may be used for power delivery, ground planes, or power planes, in legacy packages. However, simply removing these power planes risks load line deterioration of the power delivery network by 1 to several milliohms. This is addressed, in embodiments described herein, by elevating traces above a package surface to improve a power delivery load line. In embodiments, these elevated traces, or electrical conductors, may be used on the package substrate surface to improve power delivery performance. The power delivery performance may be improved by reducing the equivalent series resistance (ESR) of the power delivery network. Routing power delivery on a side, or outside, the die shadow allows smaller ESR values by thickening the trace on the surface.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

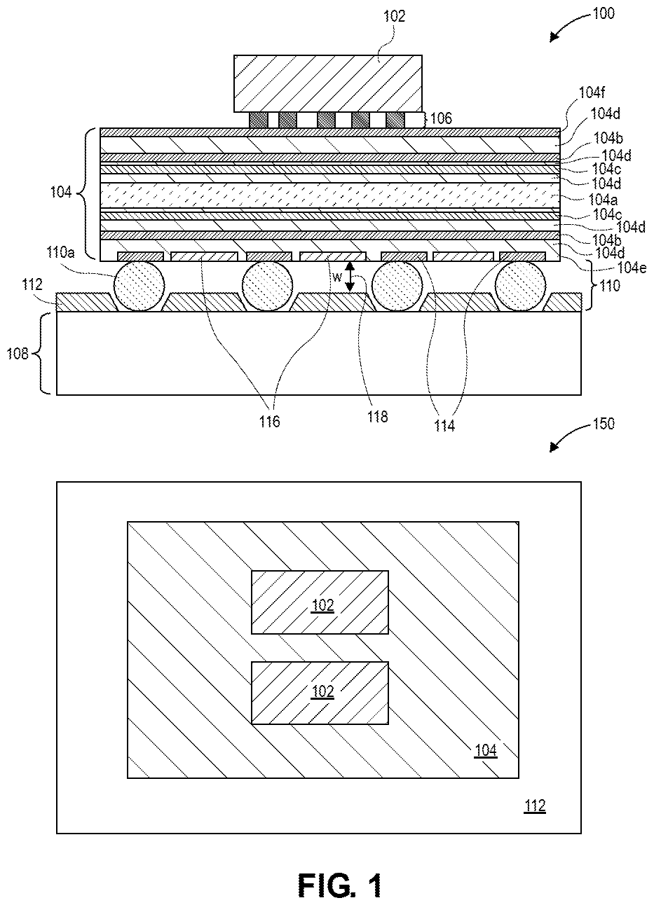

FIG. 1 illustrates a cross section side view and a top-down view of a legacy package coupled with a PCB, where a package substrate includes multiple power planes. Legacy system 100 includes dies 102 that are coupled to a package substrate 104. In implementations, the dies 102 may be coupled to the package substrate 104 using die connectors 106. In embodiments, die connectors 106 may include a BGA, micro bumps, wire bonds, or bump studs.

The package substrate 104 may be physically and/or electrically coupled with a PCB 108 using a BGA 110 that includes a plurality of balls 110a. In implementations, there may be a solder resist layer 112 on top of the PCB 108 that may surround the BGA 110. During operation, signals and/or power may be routed between the PCB 108 and the dies 102 using the BGA 110, the package substrate 104, and the die connectors 106.

In legacy implementations, the package substrate 104 may include multiple layers. For example, a core 104a may be used to provide rigidity or certain thermal characteristics to the package substrate 104. The core may also be used to embed components such as inductors, capacitors required for the operation of the die 102. In addition, various routing layers 104b may be used to route signals, power, or ground. Legacy package substrate 104 also includes power planes 104c that may be dedicated to power delivery. In implementations, multiple power planes 104c may be used to provide separate power domains, for example 1.3V and 1.1V switching voltages that may be used by separate dies 102. Separate power domains may be dedicated to different circuits, for example a graphics circuit may require a different power domain than the CPU core or a memory physical layer. Dielectric layers 104d may provide separation for the routing layers 104b and power planes 104c. In implementations, vias (not shown) may provide electrical connections between the various layers.

In implementations, a top layer 104f may include traces (not shown) to electrically couple the package substrate 104 with the die connector 106. A bottom layer 104e may include a plurality of contacts 114 to electrically couple with the BGA 110. In implementations, routings 116 may be used as ground reference (VSS) for signals and power through package substrate 104. In these legacy implementations, there may be a distance “w” 118 between the bottom layer 104e of the substrate package 104 and the top of the PCB 108, which may include the top of the solder resist layer 112, between the individual balls 110a of the BGA 110. Diagram 150 shows a top-down view of legacy system 100.

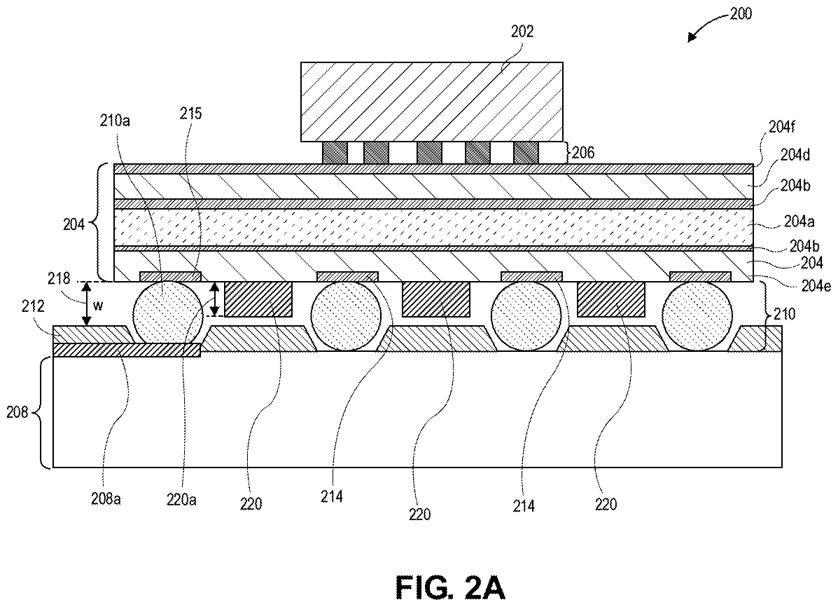

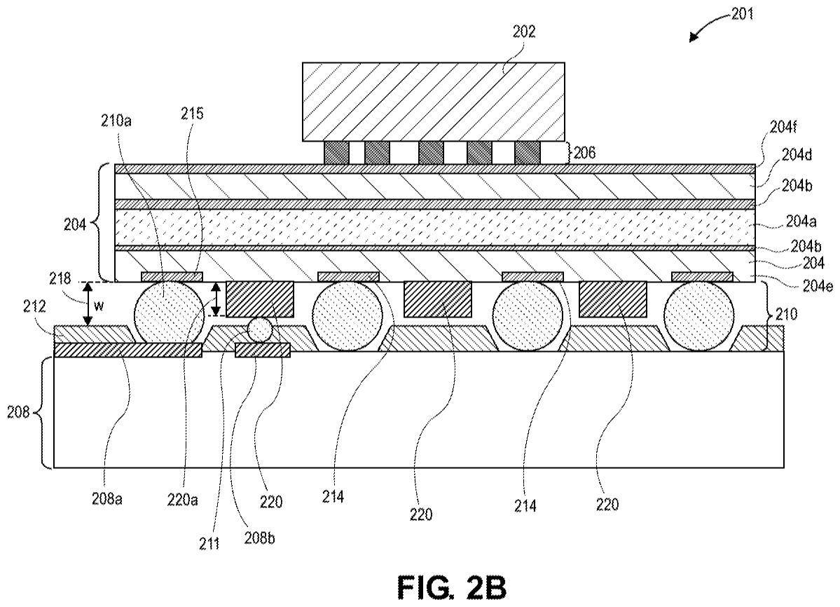

FIGS. 2A-2B illustrate cross section side views of a package that includes electrical conductors on a side of a package substrate that extend from a surface of the package substrate, in accordance with various embodiments. FIG. 2A includes system 200, which may be similar to system 100 of FIG. 1, includes dies 202 that are electrically and physically coupled with a package substrate 204 using die connectors 206. These may be similar to dies 102, package substrate 104, and die connectors 106 of FIG. 1. It should be appreciated that dies 102 are not limited to dies and may be other packages or other devices that may be physically and/or electrically coupled with the package substrate 204.

The package substrate 204 may then be physically and electrically coupled with the PCB 208 using BGA 210, which may be similar to PCB 108 and BGA 110 of FIG. 1. A solder resist layer 212, which may also be a solder mask layer, and which may be similar to solder resist layer 112 of FIG. 1, may be on top of the PCB 208 and surround the BGA 210. In embodiments, there may be an electrical routing 208a on the surface of the PCB 208 that couples with ball 210a of the BGA 210 to provide power to the ball 210a. In embodiments, there may be a distance “w” 218 between the bottom of the package substrate 204 and the top of the solder resist layer 212.

The package substrate 204 may include a core 204a, routing layers 204b, and dielectric layers 204d, which may be similar to core 104a, routing layers 104b, and dielectric layers 104d of FIG. 1. A top layer 204f, which may be similar to 104f of FIG. 1, may include routings (not shown) that electrically couple the package substrate 204 with the die connector 206. A bottom layer 204e may include a plurality of contacts 214, which may be similar to bottom layer 104e and plurality of contacts 114 of FIG. 1, to electrically couple with the BGA 210.

As shown in this embodiment, some of the dedicated power planes, for example the power planes 104c of FIG. 1, have been removed from the package substrate 204. Instead, power is routed through one or more electrical conductors 220 that are coupled to and extend from the bottom layer 204e of the package substrate 204. In embodiments, the bottom layer 204e may be referred to as a second level interconnect (SLI) interface. In embodiments, the electrical conductors 220 may be dimensioned so that they are disposed between the individual balls 210a of the BGA 210 without directly electrically contacting the individual balls 210a. In embodiments, the electrical conductors 220 may have a height 220a that is less than or equal to the distance “w” 218.

In embodiments, the electrical conductors 220 may be referred to as power corridors, power planes, power rails, power nets, or electrical buses. In embodiments, the electrical conductors 220 may include copper, or may include some other electrically conductive material such as gold or aluminum. In embodiments, a thickness of the electrical conductors 220 may range from 30 μm to 150 μm, which may facilitate power delivery. This may be substantially thicker than a thickness of the plurality of contacts 214 that may be used for signaling, including high-speed and control signaling. In embodiments, a thickness of a contact 215 that is electrically coupled with the electrical routing 208a may be different than a thickness of the plurality of contacts 214, for example if power to the electrical conductors 220 from the PCB 208 flows through the contact 215. In other embodiments, thicknesses may be the same. In embodiments, the overall cross-section may define the current carrying capability.

In embodiments, the electrical conductors 220 may be applied to the package substrate 204 using a metal deposition technique, such as direct plating or cold spray. In embodiments, electroplating may involve creating a seed layer within the substrate, wherein the substrate is submerged in a copper-based solution. An electrochemical process then enables the migration of copper particles from the solution to the seed layer. Growing fixed copper using the electroplating process may be a lengthy process. In embodiments, a solution may then be used that contains copper nanoparticles. The solution is sprayed on the substrate, for example at room temperature, to form an electrical conductor on the substrate. The cold spray process may be used to create thick copper layers in a relatively short time. In embodiments, different types of metals and nonmetals, such as diamond, may be used in the cold spray process.

In other embodiments, the electrical conductors 220 may be pre-formed and attached to the package substrate 204 during the assembly process. In embodiments, the electrical conductors 220 may have a uniform thickness, or may have a variable thickness that may depend on the routing and constraints in the SLI BGA 210 during operation. In embodiments, plated or filled vias (not shown), in addition to power routings (not shown) may be used to bring power from the electrical conductors 220 into the package substrate 204. In addition, the electrical conductors 220 may be coupled with one or more balls of the BGA 210 to route power between the one or more balls, as discussed further below.

In embodiments, the electrical conductors 220 may be a single electrical conductor that routes a single power domain. In other embodiments, the electrical conductors 220 may include multiple conductors that are electrically isolated from each other, where each may be associated with a different power domain. In some embodiments, a non-electrically conductive protective layer such as epoxy, solder mask, silicon nitride, silicon dioxide may be used surrounding a portion of the electrical conductor 220, for example to prevent corrosion or prevent an unintentional electrical short.

FIG. 2B shows system 201, which is an embodiment of a variation of system 200 of FIG. 2A, where, the electrical conductors 220 may be connected in parallel to a lane on the board to further reduce the load line. A trace 208b may be formed on the surface layer of the PCB 208 and covered with the solder resist layer 212. Electrical conductor 220 may be connected to 208b by using connector 211, which may be a solder paste or solder ball. The equivalent thickness resulting from trace 208b and electrical conductors 220 reduces the equivalent series resistance of the associated power domain, therefore resulting in a lower load line.

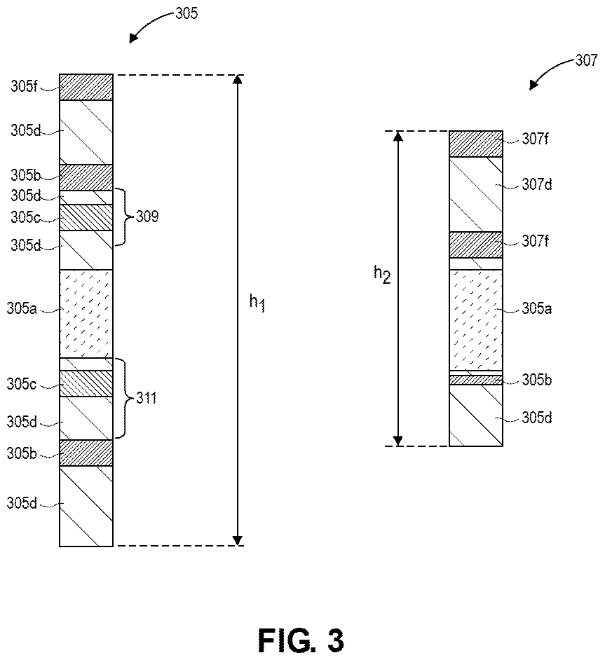

FIG. 3 shows a comparison between the number of layers of a legacy package substrate and the number of layers of a package that includes electrical conductors on a side of the package, in accordance with various embodiments. Diagram 305 shows a cross-section of a package substrate that may be similar to legacy package substrate 104 of FIG. 1. The package substrate layers 305a, 305b, 305c, 305d, 305f may be similar to package substrate layers 104a, 104b, 104c, 104d, 104f of FIG. 1. Diagram 307 shows a cross section side view of a package substrate that may be similar to package substrate 204 of FIG. 2. The package substrate layers 307a, 307b, 307d, 307f may be similar to package substrate layers 204a, 204b, 204d, 204f of FIG. 2

As discussed above with respect to FIG. 2, embodiments that include electrical conductors 220 on the outside surface of package substrate 204 remove the need for the two power planes 305c. In addition, the dielectric layers 305d on either side of the two power planes 305c are no longer needed to electrically isolate the power planes 305c. As a result, sections 309 and 311 of the layers of legacy package substrate shown in diagram 305 are no longer needed, and do not appear in the package substrate shown in diagram 307. Thus, the layer count may be reduced, reducing an overall height h1 of legacy package substrate 104 of FIG. 1 to an overall height h2 of package substrate 204 of FIG. 2.

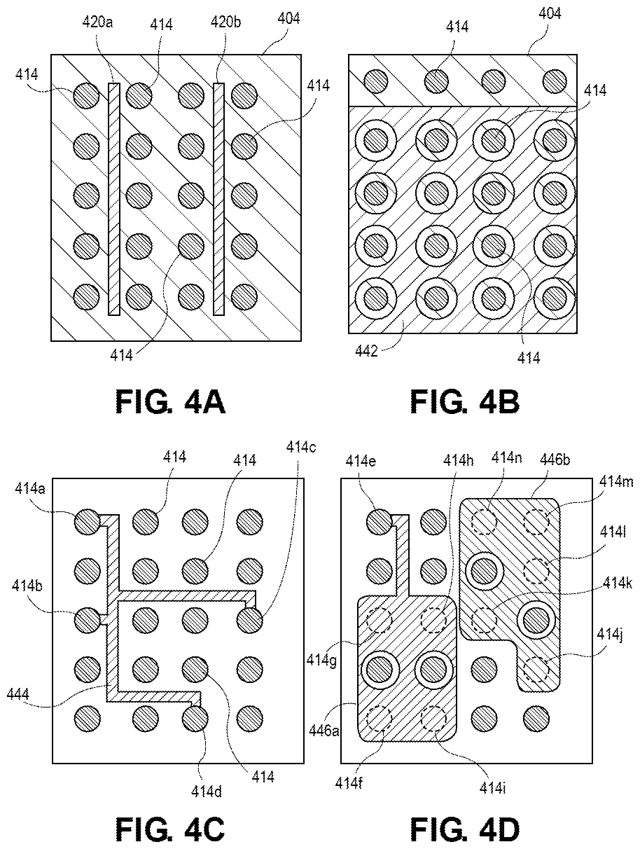

FIGS. 4A-4D illustrate layouts of one or more electrical conductors on a side of a package substrate, in accordance with various embodiments. FIG. 4A shows a bottom-up cross-section view of bottom of a portion of a package substrate, which may be similar to package substrate 204, and in particular may be similar to layer 204e of FIG. 2. An array of contacts 414, which may be similar to contacts 214 or 215 on layer 204e of FIG. 2, are shown. In embodiments, the array of contacts 414 may be coupled with a BGA (not shown) that may be similar to BGA 210 of FIG. 2.

In embodiments, a first electrical conductor 420a, which may be similar to electrical conductor 220 of FIG. 2, may be placed on the bottom surface of the substrate 404 among a first group of the array of contacts 414. A second electrical conductor 420b may be similarly placed on the bottom surface of substrate 404 among a second group of the array of contacts 414. As shown, the first electrical conductor 420a and the second electrical conductor 420b are electrically isolated from each other, and are not directly electrically coupled with any of the array of contacts 414. In embodiments, the first electrical conductor 420a may be associated with a first power domain, and the second electrical conductor 420b may be associated with a second power domain.

FIG. 4B shows a bottom-up cross-section view of bottom of a portion of a package substrate 404, where a third electrical conductor 442 may be placed on the bottom surface of substrate 404 surrounding a group of the array of contacts 414 in a honeycomb-like or mesh-like configuration to form a power web. In embodiments, the third electrical conductor 442 may form a plane or a sub-plane.

FIG. 4C shows a bottom-up cross-section view of a bottom of a portion of a package substrate 404, that includes a fourth electrical conductor 444 that electrically couples contacts 414a, 414b, 414c, and 414d. In embodiments, contact 414a may be similar to contact 215 of FIG. 2, where power is provided to the contact 215 through the solder ball 210a from the electrical routings 208a within PCB 208 of FIG. 2. In this way, the fourth electrical conductor 444 may be used to provide power to electrical contacts 414a, 414b, 414c, 414d. In embodiments, this may also reduce the power routing requirements within a PCB coupled with the package substrate 404, for example PCB of FIG. 2. In embodiments, the fourth electrical conductor 444 may be covered by a protective layer (not shown) and its width may be maximized, within the constraints of SLI design rules, in order to minimize the loan line associated with a power domain.

FIG. 4D shows a bottom-up cross-section view of a bottom of a portion of a package substrate 404, that includes a fifth electrical conductor 446a that is electrically coupled to contact 414e and to contact 414f that both provide electrical power from the PCB (not shown) to the fifth electrical conductor 446a. The fifth electrical conductor 446a, that has a partial honeycomb shape, then provides power to contacts 414g, 414h, 414i. Similarly, a sixth electrical conductor 446b is electrically coupled to contact 414j that receives power from the PCB (not shown). The sixth electrical conductor 446b may be directly electrically coupled with contacts 414k, 4141, 414m, 414n. Note that the sixth electrical conductor 446b is also in a partial honeycomb shape. Note as well that the fifth electrical conductor 446a and the sixth electrical conductor 446b may be both electrically isolated from each other, but may both be between two contacts 414h, 414k.

Note that in embodiments (not shown), power may be received from an electrical conductor such as sixth electrical conductor 446b by metal vias (not shown) that extend within a substrate, such as substrate 204 of FIG. 2, through the bottom of the substrate and down to directly electrically couple with the electrical conductor.

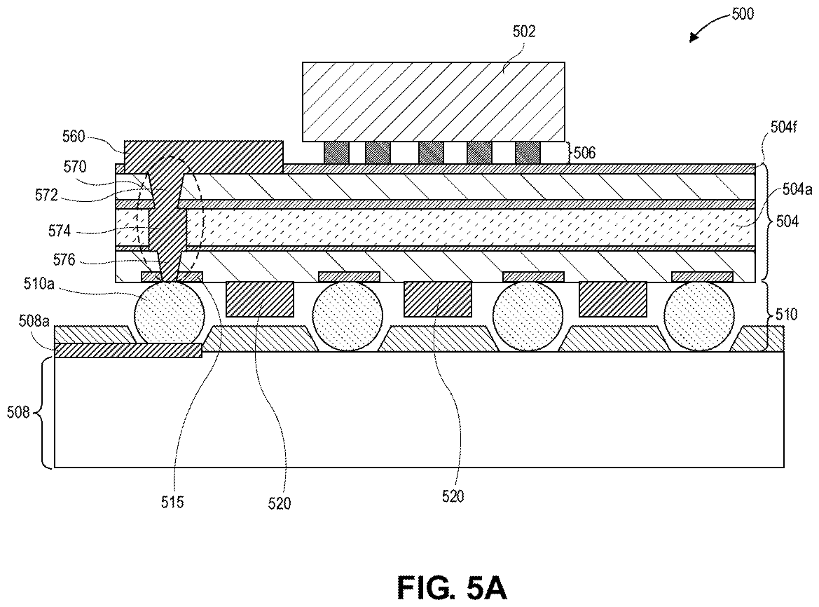

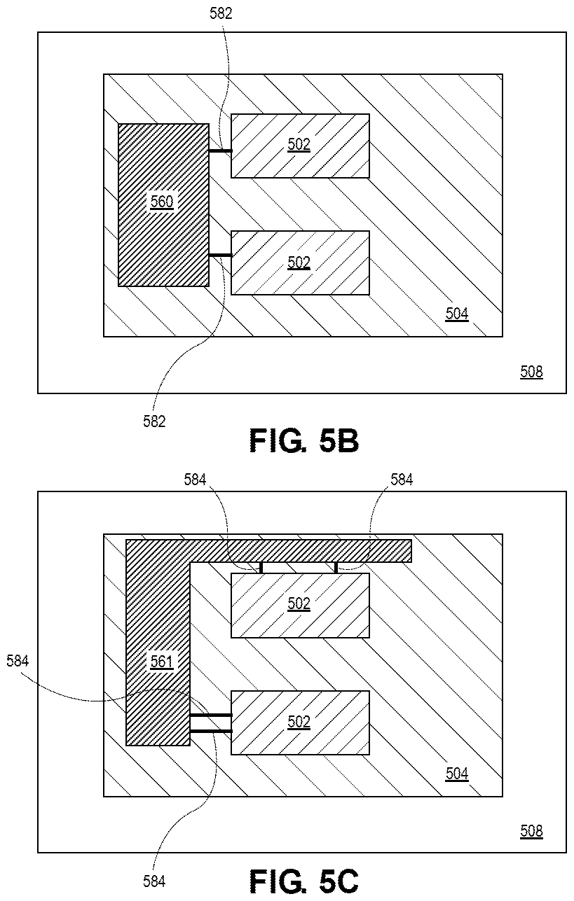

FIG. 5A illustrates a cross section side view of a package that includes an electrical conductor on a die side surface of a package substrate, in accordance with various embodiments. System 500, which may be similar to system 200 of FIG. 2, includes dies 502 that may electrically and physically couple with a package substrate 504 using die connectors 506. These may be similar to dies 202, package substrate 204, and die connectors 206 of FIG. 2. The package substrate 504 may be physically and electrically coupled with a PCB 508 using BGA 510. In embodiments, there may be an electrical routing 508a on the surface of the PCB 508 that couples with ball 510a of the BGA 510 to provide power to the ball 510a. These may be similar to PCB 208, BGA 210, electrical routing 208a, and ball 210a of FIG. 2. Electrical conductors 520, which may be similar to electrical conductors 220 of FIG. 2, may be coupled with a bottom of the package substrate 504.

A die side electrical conductor 560, which may be similar to electrical conductor 220 of FIG. 2, may be coupled with a top of the package substrate 504. In embodiments, the die side electrical conductor 560 may be used to route power to the dies 502 on the top side of the package substrate 504. In embodiments, the die side electrical conductor 560 may be electrically coupled with a vertical electrical coupling 570 through the package substrate 504. In embodiments, the vertical electrical coupling 570 may be electrically coupled to a contact 515, which may be similar to contacts 214, 215 of FIG. 2, that in turn may be electrically coupled with ball 510a of the BGA 510.

In embodiments, the vertical electrical coupling 570 may include various conductive components. For example, the vertical electrical coupling 570 may include upper vias 572, through holes 574, and lower vias 576 that are electrically coupled. In embodiments, the upper vias 572, through holes 574, and lower vias 576 may be plated or filled with an electrically conductive metal or with some other electrically conductive substance. In embodiments, the conductive components within the vertical electrical coupling 570 may be formed using techniques known in the art. In particular, through holes 574 may extend through a core 504a of the package substrate 504, which may be similar to core 204a of FIG. 2.

In embodiments, the die side electrical conductor 560 may be electrically coupled with the die connectors 506 using electrical routings that may be found in the top layer 504f of the package substrate 504, which may be similar to top layer 204f of FIG. 2. In embodiments, a thickness of the die side electrical conductor 560.

In embodiments, a geometry including a thickness of the die side electrical conductor 560 may be selected based upon a power profile for the dies 502 during operation of the system 500. In addition, a size of the vertical electrical coupling 570, as well as a number of vertical electrical coupling 570 to electrically couple with the die side electrical conductor 560 may also be based on the power profile. It should be appreciated that although FIG. 5A refers to dies 502, other packages or other electrical components may be used in place of the dies 502.

FIG. 5B shows a top-down view of system 500, with dies 502 on package substrate 504, which in turn is coupled with the PCB 508. In embodiments, the die side electrical conductor 560 may be electrically coupled with the dies 502 using routings 582 on the surface of the package substrate 504. In embodiments, these routings may be within the top layer 504f of the package substrate 504 as shown in diagram 500. As shown, the die side electrical conductor 560 is substantially rectangular.

FIG. 5C shows a top-down view of system 500, with dies 502 on package substrate 504, which in turn is coupled with the PCB 508. In embodiments, the die side electrical conductor 561 may be electrically coupled with the dies 502 using routings 584 on the surface of the package substrate 504. In embodiments, these routings may be within the top layer 504f of the package substrate 504 as shown in diagram 500. As shown, the die side electrical conductor 561 is an “L” shape that may provide a shorter route between various areas of the dies 502. In embodiments, the die side electrical conductor 561 may be of any shape. To deliver more power, a larger cross-sectional area may be preferred, which may come from a combination of width and thickness of the die side electrical conductor 561. In embodiments, the routings 584 may be sooner traces on a package to connect power from the die side electrical conductor 561 to power bumps on the dies 502.

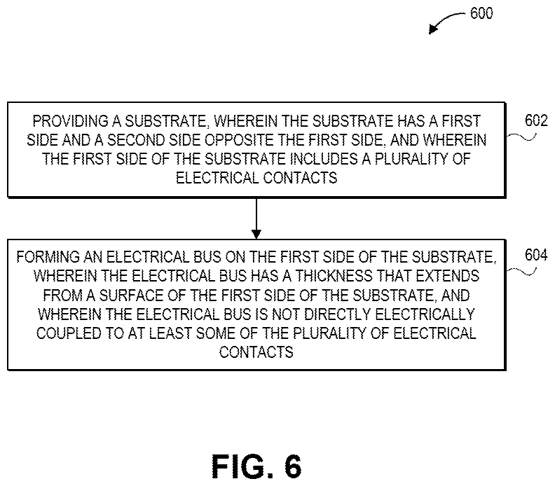

FIG. 6 illustrates an example of a process for creating a package that includes a substrate with an electrical conductor on a side of the package substrate, in accordance with various embodiments. Process 600 may be performed by one or more elements, techniques, processes, or systems that may be described herein, and in particular with respect to FIGS. 1-5C.

At block 602, the process may include providing a substrate, wherein the substrate has a first side and a second side opposite the first side, and wherein the first side of the substrate includes a plurality of electrical contacts. In embodiments, the substrate may be similar to package substrate 104 of FIG. 1, package substrate 204 of FIG. 2, package substrate 404 of FIGS. 4A-4D, or package substrate 504 of FIGS. 5A-5C. In embodiments, the plurality of electrical contacts may be similar to electrical contacts 114 of FIG. 1, electrical contacts 214, 215 of FIG. 2, electrical contacts 414, 414a-414n of FIGS. 4A-4D, or electrical contact 515 of FIG. 5A.

At block 604, the process may further include forming an electrical bus on the first side of the substrate, wherein the electrical bus has a thickness that extends from a surface of the first side of the substrate, and wherein the electrical bus is not directly electrically coupled to at least some of the plurality of electrical contacts. In embodiments, the electrical bus may be similar to electrical conductors 220 of FIG. 2, electrical conductors 420a, 420b of FIG. 4A, electrical conductor 442 of FIG. 4B, electrical conductor 444 of FIG. 4C, or electrical conductors 446a, 446b of FIG. 4D. In embodiments, the electrical bus may be applied to a surface of the substrate using a direct plating technique or a cold spray technique.

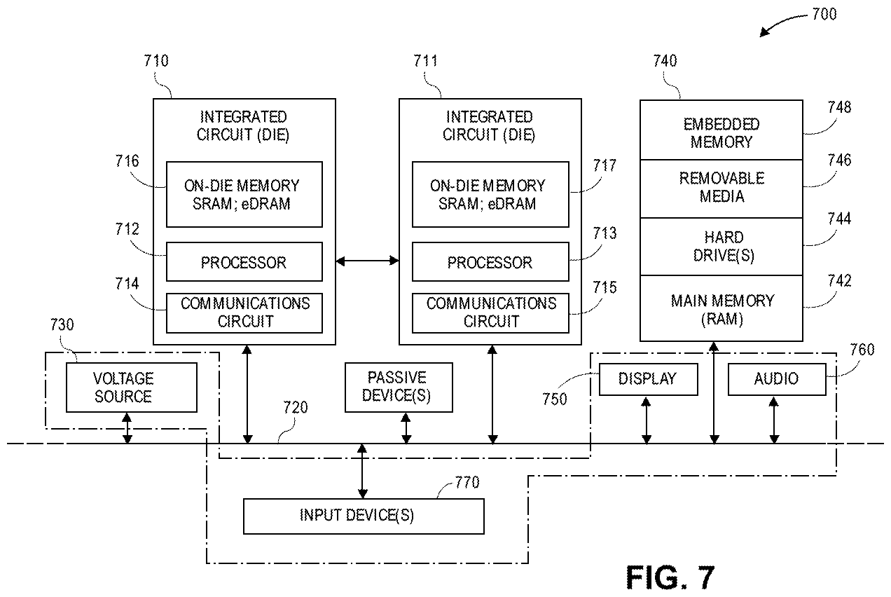

FIG. 7 is a schematic of a computer system 700, in accordance with an embodiment of the present invention. The computer system 700 (also referred to as the electronic system 700) as depicted can embody an electrical conductor extending from a surface of a substrate, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, an electrical conductor extending from a surface of a substrate, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having an electrical conductor extending from a surface of a substrate, according to any of the several disclosed embodiments and their equivalents, an electronic system, a computer system, one or more methods of fabricating an integrated circuit, and one or more methods of fabricating an electronic assembly that includes a package substrate having an electrical conductor extending from a surface of a substrate, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having an electrical conductor extending from a surface of a substrate embodiments and their equivalents. A foundation substrate may be included, as represented by the dashed line of FIG. 7. Passive devices may also be included, as is also depicted in FIG. 7.

### EXAMPLES

The following paragraphs describe examples of various embodiments.

Example 1 is an apparatus comprising: a substrate with a first side and a second side opposite the first side; a plurality of electrical contacts on the first side of the substrate; and an electrical conductor on the first side of the substrate and extending from a surface of the first side of the substrate, the electrical conductor electrically coupled with at least one of the plurality of electrical contacts.

Example 2 includes the apparatus of example 1, or of any other example or embodiment herein, wherein the electrical conductor is electrically isolated from another one of the plurality of electrical contacts.

Example 3 includes the apparatus of example 1, or of any other example or embodiment herein, wherein the electrical conductor has a thickness ranging from 30 μm to 150 μm.

Example 4 includes the apparatus of example 1, or of any other example or embodiment herein, wherein the electrical conductor includes copper.

Example 5 includes the apparatus of example 1, or of any other example or embodiment herein, wherein the electrical conductor further includes a protective layer surrounding at least a portion of the electrical conductor.

Example 6 includes the apparatus of example 1, or of any other example or embodiment herein, wherein the electrical conductor forms a plane that surrounds at least one of the plurality of electrical contacts, and wherein the electrical conductor is electrically isolated from the at least one of the plurality of electrical contacts.

Example 7 includes the apparatus of example 1, or of any other example or embodiment herein, wherein the electrical conductor is a first electrical conductor, and wherein the at least one of the plurality of electrical contacts is a first of the at least one of the plurality of electrical contacts; and further comprising: a second electrical conductor on the first side of the substrate, wherein the second electrical conductor is electrically isolated from the first electrical conductor; and wherein the second electrical conductor is electrically coupled with a second of the at least one of the plurality of electrical contacts.

Example 8 includes the apparatus of example 7, or of any other example or embodiment herein, wherein the first electrical conductor is associated with a first power domain, and the second electrical conductor is associated with a second power domain.

Example 9 includes the apparatus of example 1, or of any other example or embodiment herein, wherein the electrical conductor has a uniform thickness.

Example 10 includes the apparatus of example 1, or of any other example or embodiment herein, wherein the first side of the substrate is coupled with a printed circuit board (PCB), wherein the plurality of contacts are coupled with the PCB using a ball grid array (BGA), and wherein the electrical conductor is electrically coupled with a first solder ball of the BGA and is electrically isolated from a second solder ball of the BGA.

Example 11 includes the apparatus of example 10, or of any other example or embodiment herein, wherein the first solder ball is associated with a power domain.

Example 12 includes the apparatus of example 1, or of any other example or embodiment herein, further comprising a die coupled with the first side of the substrate, wherein the die is electrically coupled with the electrical conductor, and wherein the electrical conductor is electrically coupled with the second side of the substrate through electrical pathways in the substrate.

Example 13 includes the apparatus of example 1, or of any other example or embodiment herein, wherein a thickness of the electrical conductor is greater than a thickness of another trace on the substrate.

Example 14 is a system comprising: a package that includes: a substrate with a first side and a second side opposite the first side; a plurality of electrical contacts on the first side of the substrate; and a power rail on the first side of the substrate, the power rail with a thickness that extends from the first side of the substrate, and wherein the power rail is not in direct electrical contact with at least some of the plurality of electrical contacts; and a board coupled with the first side of the substrate, wherein the power rail is not in direct physical contact with the board.

Example 15 includes the system of example 14, or of any other example or embodiment herein, further comprising a ball grid array (BGA) between the board and the first side of the substrate, wherein the power rail is in direct electrical contact with a first ball and with a second ball of the BGA.

Example 16 includes the system of example 15, or of any other example or embodiment herein, wherein the first ball is directly electrically coupled with the board, and wherein the second ball is not directly electrically coupled with the board.

Example 17 includes the system of example 14, or of any other example or embodiment herein, wherein the board is a printed circuit board (PCB).

Example 18 includes a system of example 14, or of any other example or embodiment herein, further comprising an electrical component coupled with the second side of the substrate, wherein the electrical component is electrically coupled with the power rail.

Example 19 includes the system of example 18, or of any other example or embodiment herein, wherein the electrical component includes a die.

Example 20 includes a system of example 18, or of any other example or embodiment herein, wherein the electrical component is a plurality of electrical components.

Example 21 is a method comprising: providing a substrate, wherein the substrate has a first side and a second side opposite the first side, and wherein the first side of the substrate includes a plurality of electrical contacts; and forming an electrical bus on the first side of the substrate, wherein the electrical bus has a thickness that extends from a surface of the first side of the substrate, and wherein the electrical bus is not directly electrically coupled to at least some of the plurality of electrical contacts.

Example 22 includes the method of example 21, or of any other example or embodiment herein, further comprising: coupling the first side of the substrate to a printed circuit board (PCB), wherein the coupling includes coupling a ball grid array (BGA) to the plurality of electrical contacts and coupling the BGA to the PCB.

Example 23 includes the method of example 22, or of any other example or embodiment herein, wherein the plurality of electrical contacts is a first plurality of electrical contacts; and wherein forming the electrical bus further includes electrically coupling a second plurality of electrical contacts.

Example 24 includes the method of example 21, or of any other example or embodiment herein, wherein the electrical bus is a first electrical bus; and further comprising: forming a second electrical bus on the second side of the substrate; and electrically coupling the first electrical bus and the second electrical bus using an electrical connection within the substrate that extends from the first side of the substrate to the second side of the substrate.

Example 25 includes the method of example 21, or of any other example or embodiment herein, wherein forming the electrical bus further includes forming the electrical bus using a selected one of: direct plating or cold spray.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. An apparatus comprising:
a substrate with a first side and a second side opposite the first side;
a plurality of electrical contacts on the first side of the substrate; and
an electrical conductor on the first side of the substrate and extending from a surface of the first side of the substrate, the electrical conductor electrically coupled with at least one of the plurality of electrical contacts.

2. The apparatus of claim 1, wherein the electrical conductor is electrically isolated from another one of the plurality of electrical contacts.

3. The apparatus of claim 1, wherein the electrical conductor has a thickness ranging from 30 μm to 150 μm.

4. The apparatus of claim 1, wherein the electrical conductor includes copper.

5. The apparatus of claim 1, wherein the electrical conductor further includes a protective layer surrounding at least a portion of the electrical conductor.

6. The apparatus of claim 1, wherein the electrical conductor forms a plane that surrounds at least one of the plurality of electrical contacts, and wherein the electrical conductor is electrically isolated from the at least one of the plurality of electrical contacts.

7. The apparatus of claim 1, wherein the electrical conductor is a first electrical conductor, and wherein the at least one of the plurality of electrical contacts is a first of the at least one of the plurality of electrical contacts; and further comprising:
a second electrical conductor on the first side of the substrate, wherein the second electrical conductor is electrically isolated from the first electrical conductor; and
wherein the second electrical conductor is electrically coupled with a second of the at least one of the plurality of electrical contacts.

8. The apparatus of claim 7, wherein the first electrical conductor is associated with a first power domain, and the second electrical conductor is associated with a second power domain.

9. The apparatus of claim 1, wherein the electrical conductor has a uniform thickness.

10. The apparatus of claim 1, wherein the first side of the substrate is coupled with a printed circuit board (PCB), wherein the plurality of contacts are coupled with the PCB using a ball grid array (BGA), and wherein the electrical conductor is electrically coupled with a first solder ball of the BGA and is electrically isolated from a second solder ball of the BGA.

11. The apparatus of claim 10, wherein the first solder ball is associated with a power domain.

12. The apparatus of claim 1, further comprising a die coupled with the first side of the substrate, wherein the die is electrically coupled with the electrical conductor, and wherein the electrical conductor is electrically coupled with the second side of the substrate through electrical pathways in the substrate.

13. The apparatus of claim 1, wherein a thickness of the electrical conductor is greater than a thickness of another trace on the substrate.

14. A system comprising:
a package that includes:
a substrate with a first side and a second side opposite the first side;
a plurality of electrical contacts on the first side of the substrate; and
a power rail on the first side of the substrate, the power rail with a thickness that extends from the first side of the substrate, and wherein the power rail is not in direct electrical contact with at least some of the plurality of electrical contacts; and
a board coupled with the first side of the substrate, wherein the power rail is not in direct physical contact with the board.

15. The system of claim 14, further comprising a ball grid array (BGA) between the board and the first side of the substrate, wherein the power rail is in direct electrical contact with a first ball and with a second ball of the BGA.

16. The system of claim 15, wherein the first ball is directly electrically coupled with the board, and wherein the second ball is not directly electrically coupled with the board.

17. The system of claim 14, wherein the board is a printed circuit board (PCB).

18. The system of claim 14, further comprising an electrical component coupled with the second side of the substrate, wherein the electrical component is electrically coupled with the power rail.

19. The system of claim 18, wherein the electrical component includes a die.

20. The system of claim 18, wherein the electrical component is a plurality of electrical components.

21. A method comprising:
providing a substrate, wherein the substrate has a first side and a second side opposite the first side, and wherein the first side of the substrate includes a plurality of electrical contacts; and
forming an electrical bus on the first side of the substrate, wherein the electrical bus has a thickness that extends from a surface of the first side of the substrate, and wherein the electrical bus is not directly electrically coupled to at least some of the plurality of electrical contacts.

22. The method of claim 21, further comprising:
coupling the first side of the substrate to a printed circuit board (PCB), wherein the coupling includes coupling a ball grid array (BGA) to the plurality of electrical contacts and coupling the BGA to the PCB.

23. The method of claim 22, wherein the plurality of electrical contacts is a first plurality of electrical contacts; and
wherein forming the electrical bus further includes electrically coupling a second plurality of electrical contacts.

24. The method of claim 21, wherein the electrical bus is a first electrical bus; and
further comprising:
forming a second electrical bus on the second side of the substrate; and
electrically coupling the first electrical bus and the second electrical bus using an electrical connection within the substrate that extends from the first side of the substrate to the second side of the substrate.

25. The method of claim 21, wherein forming the electrical bus further includes forming the electrical bus using a selected one of: direct plating or cold spray.
